(19) United States
(12) Patent Application Publication
(10) Pub. No.: US 2024/0237291 A1
(43) Pub. Date: Jul. 11, 2024

(54) MODULE SOCKET ASSEMBLY WITH AIR DUCT

(71) Applicant: ACCTON TECHNOLOGY CORPORATION, Hsinchu (TW)

(72) Inventor: SHU-KAI CHANG, Hsinchu County (TW)

(73) Assignee: ACCTON TECHNOLOGY CORPORATION, Hsinchu (TW)

(21) Appl. No.: 18/542,796

(22) Filed: Dec. 18, 2023

Related U.S. Application Data
(60) Provisional application No. 63/437,233, filed on Jan. 5, 2023.

(51) Int. Cl. H05K 7/20

(52) U.S. Cl. CPC H05K 7/2039

(57) ABSTRACT

A module socket assembly with an air duct includes a module socket including a circuit board and a front panel disposed on a side of the circuit board. A module casing is disposed on the circuit board. A front end of the module casing has a module jack and passes through a module casing opening of the front panel. The front panel has an air duct opening. An air duct covers the module casing, passes through the air duct opening, and has an air duct body. An air passage extending in a front-rear direction is formed inside the air duct body. With the air duct, the present disclosure allows an air current entering from a front end of the air duct to concentratedly pass through a heat sink of the module casing, thereby preventing dissipation of the air current.

### BACKGROUND OF THE INVENTION

### Technical Field

The present disclosure relates generally to an electronic module socket, and more particularly to a module socket assembly with an air duct.

### Description of Related Art

An existing network communication host is characterized by a module casing disposed on a circuit board. A front end of the module casing has a module jack for inserting an optical fiber module, and the optical fiber module is electrically connected to the circuit board so as to be hot-pluggable on the network communication host.

The temperature of the optical fiber module in operation can reach 70° C. To cool down the optical fiber module and prevent the optical fiber module from overheating, typically a heat sink is disposed on the module casing, so that the heat sink dissipates the heat from the module casing and the optical fiber module inside the module casing, thereby cooling down the optical fiber module. However, only disposing the heat sink on the module casing is not sufficiently effective for the purpose of heat dissipation, because even though air current enters spaces between fins of the heat sink, not all the air current passes through the heat sink; instead, some of the air current simply dissipates. As a result, the heat sink has poor heat dissipation efficiency and thereby is not effective in cooling down the optical fiber module.

### BRIEF SUMMARY OF THE INVENTION

In view of the above, the primary objective of the present disclosure is to provide a module socket assembly with an air duct, so that an air duct guides air current to pass through a module casing, thereby enhancing the heat dissipation efficiency of the module casing by the air current and the cooling efficiency.

The present disclosure provides a module socket assembly, including a module socket and an air duct. The module socket includes a circuit board and a front panel disposed on a side of the circuit board, wherein a module casing is disposed on the circuit board. An end of the front panel corresponding to the module casing has a module casing opening. A front end of the module casing passes through the module casing opening and has a module jack. A portion of the front panel adjacent to the module casing opening has an air duct opening. The air duct has an air duct body. The air duct body covers the module casing and passes through the air duct opening. The air duct body has a top board. Two side boards are formed by extending downward respectively from two opposite edges of the top board. An air passage that is extending is formed between the top board and the two side boards.

With the aforementioned design, the air duct covers the module casing and the air passage is formed inside the air duct, so that the air current that has entered the air duct is, in its entirety, forced to pass through a portion of the module casing for disposing a heat sink. Therefore, the heat dissipation efficiency of the module casing by the air current and the efficiency of cooling down the electronic module inserted into the module casing could be enhanced.

### BRIEF DESCRIPTION OF THE SEVERAL VIEWS OF THE DRAWINGS

The present disclosure will be best understood by referring to the following detailed description of some illustrative embodiments in conjunction with the accompanying drawings, in which

FIG. 1 is a perspective view of the module socket assembly with the air duct according to a first embodiment of the present disclosure;

FIG. 2 is an exploded view of the module socket assembly with the air duct according to the first embodiment of the present disclosure;

FIG. 3 is a perspective view of the module socket according to the first embodiment of the present disclosure;

FIG. 4 is a sectional view along the P4-P4 line in FIG. 3;

FIG. 5 is a perspective view, showing the air duct according to the first embodiment of the present disclosure being moved frontward;

FIG. 6 is a sectional view along the P6-P6 line in FIG. 5;

FIG. 7 is a perspective view of the module socket assembly with the air duct according to a second embodiment of the present disclosure;

FIG. 8 is an exploded view of the module socket assembly with the air duct according to the second embodiment of the present disclosure;

FIG. 9 is a sectional view along the P9-P9 line in FIG. 7;

FIG. 10 is a perspective view of the module socket assembly with the air duct according to a third embodiment of the present disclosure;

FIG. 11 is an exploded view of the module socket assembly with the air duct according to the third embodiment of the present disclosure;

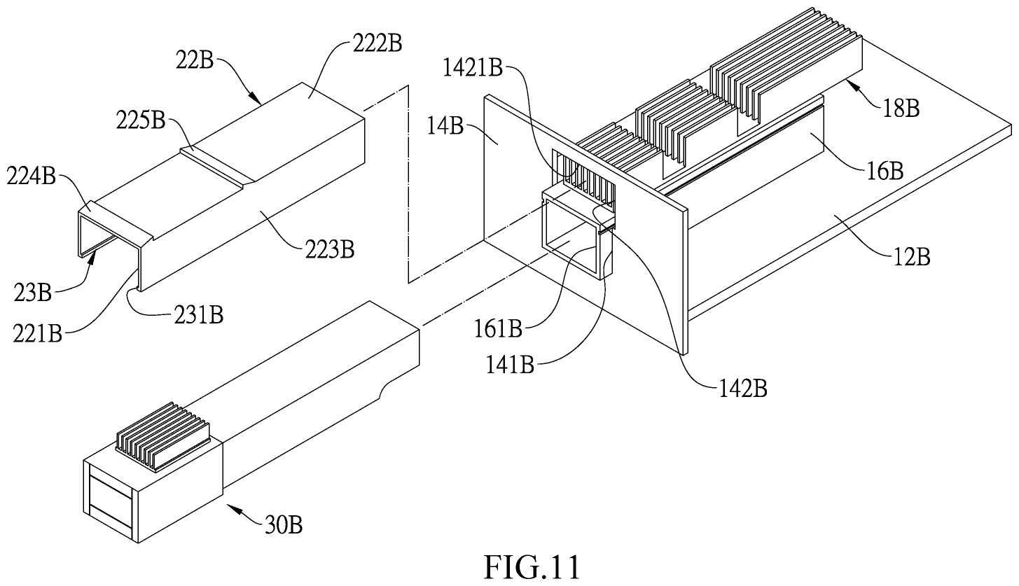

FIG. 12 is a sectional view along the P12-P12 line in FIG. 10;

FIG. 13 is a perspective view of the module socket assembly with the air duct according to a fourth embodiment of the present disclosure;

FIG. 14 is an exploded view of the module socket assembly with the air duct according to the fourth embodiment of the present disclosure;

FIG. 15 is a sectional schematic view of a part of the air duct shown in FIG. 14; and

FIG. 16 is a sectional view along the P16-P16 line in FIG. 13.

### DETAILED DESCRIPTION OF THE INVENTION

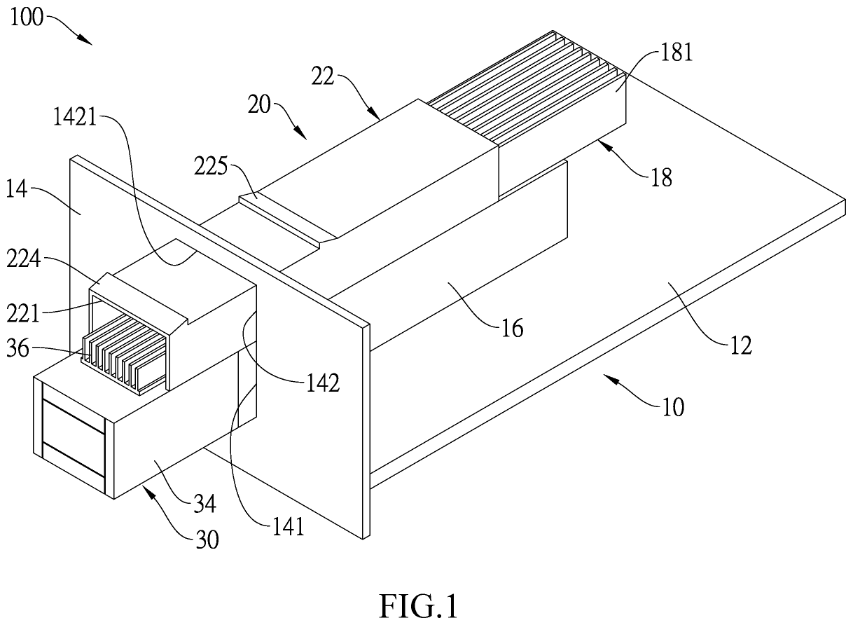

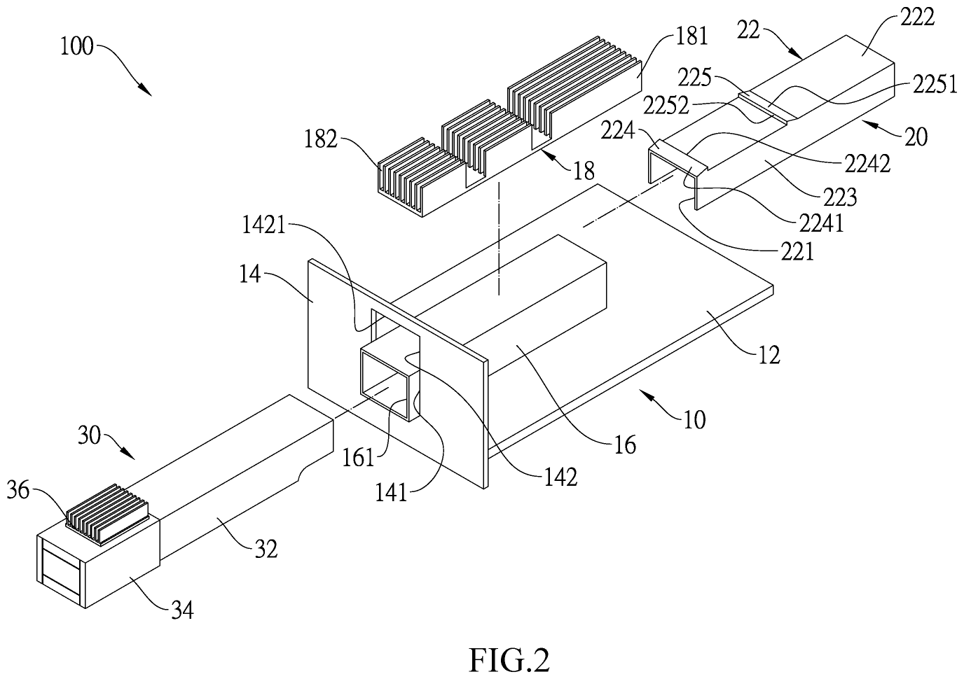

A module socket assembly with an air duct 100 according to a first embodiment of the present disclosure is illustrated in FIG. 1 and FIG. 2 and includes a module socket 10 and an air duct 20. In the description below, the terms “top”, “bottom”, “front”, “rear”, “left”, “right”, and their derivatives, should be interpreted from the exploded view of the present invention in FIG. 1. It is understood that the terminology used herein is for the purpose of describing particular embodiments only, and is not intended to limit the scope of the present invention. Two opposite directions of the module socket assembly 100 in a horizontal direction are respectively defined as “front” and “rear”. Two opposite directions of the module socket assembly 100 in a vertical direction are respectively defined as “top (or upper)” and “bottom (or lower). Two opposite directions of the module socket assembly 100 that are respectively perpendicular to the horizontal and the vertical directions are respectively defined as “left” and “right”.

The module socket 10 includes a circuit board 12 and a front panel 14. A module casing 16 is coupled to the circuit board 12. A front end of the module casing 16 has a module jack 161. A heat sink 18 is disposed on the module casing 16. The heat sink 18 has a plurality of cooling fins 181 laterally spaced apart from each other. A front end of the heat sink 18 has a plurality of holes 182. The front panel 14 is a plate that is upright and disposed on a side of the circuit board 12. In the current embodiment, the front panel 14 is a metallic plate. A position of the front panel 14 corresponding to the module casing 16 has a module casing opening 141, such that a front end of the module casing 16 passes through the module casing opening 141. A portion of the front panel 14 adjacent to the module casing opening 141 has an air duct opening 142. More specifically, the air duct opening 142 is disposed on a portion of the front panel 14 located directly in front of the heat sink 18, and gaps formed between the cooling fins 181 respectively communicate with the air duct opening 142.

The air duct 20 has an air duct body 22. The air duct body 22 covers the module casing 16 and covers at least part of the heat sink 18. An air passage 221 extending in a front-rear direction is provided inside the air duct body 22. The at least part of the heat sink 18 is located inside the air passage 221. A top surface of the module casing 16 and an inner wall of the air duct body 22 jointly enclose the at least part of the heat sink 18, so that air current passing through the holes 182 to enter the gaps between the cooling fins 181 is guided by the air duct 20, thereby preventing the air current from flowing out of the gaps between the cooling fins 181 to otherwise dissipate and preventing the heat dissipation efficiency of the heat sink 18 from being reduced. Therefore, the heat dissipation efficiency of the heat sink 18 for the module casing 16 could be enhanced.

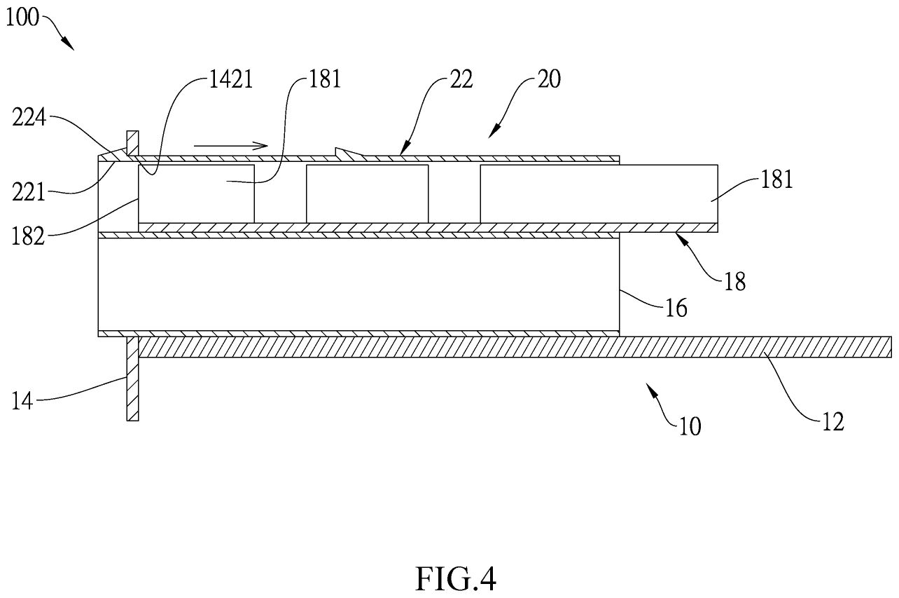

Referring to FIG. 1, FIG. 2, and FIG. 4, the module jack 161 of the module casing 16 of the present disclosure is for an electronic module 30 to be inserted and connected. In the current embodiment, the electronic module 30 is an optical fiber module, but the present disclosure is not limited thereto, as long as the electronic module 30 could be plugged into the module jack 161 of the module casing 16 to be electrically connected to the circuit board 12. The temperature of the electronic module 30 in operation could increase to around 70° C., wherein the heat generated by the electronic module 30 is thermally transferred to the module casing 16 and then is dissipated by the heat sink 18 on the module casing 16. By the air duct 20, the present disclosure forces the air current, which enter the gaps between the cooling fins 181 through the holes 182, to pass through the gaps between the cooling fins 181 and hence entirely pass through the heat sink 18 disposed on the module casing 16, so that the heat dissipation efficiency of the heat sink 18 with respect to the module casing 16 could be enhanced and the electronic module 30 inserted into the module casing 16 could be cooled more efficiently.

Referring to FIG. 1 and FIG. 2, in the first embodiment of the present disclosure, the module casing opening 141 and the air duct opening 142 of the front panel 14 are rectangular holes respectively corresponding to the module casing 16 and the air duct 20 in shape and position, and communicate with each other vertically. A side of the air duct opening 142 has a top edge 1421. In the first embodiment, the top edge 1421 of the air duct opening 142 is located on a top side of the air duct opening 142. A front of the front panel 14 and a rear of the front panel 14 located on the circuit board 12 are respectively defined as an external portion and an internal portion of the module socket 10; thus, two opposite sides of the top edge 1421 of the air duct opening 142 are an outside and an inside of the module socket 10, respectively. The air duct body 22 of the air duct 20 passes through the air duct opening 142 in an inwardly and outwardly movable manner (i.e., the air duct body 22 of the air duct 20 passes through the air duct opening 142 in a movable manner along the front-rear direction). Since the air duct opening 142, which is passed by the air duct 20, is located at a junction of the inside and the outside of the module socket 10, the inward and outward directions of the movement of the air duct 20 are equivalent to a front direction and a rear direction, respectively.

The air duct body 22 has a top board 222. Two side boards 223 are formed by extending downward respectively from two opposite edges of the top board 222. The two side boards 223 are located on a left side and a right side of the heat sink 18, respectively. In the first embodiment, two bottom edges of the two side boards 223 abut against a left edge and a right edge of the top surface of the module casing 16, respectively, and the air passage 221 is formed between the top board 222 and the two side boards 223. A first raised portion 224 and a second raised portion 225 are disposed on portions of the air duct body 22 located on an external portion and an internal portion of the front panel 14, respectively. More specifically, the first raised portion 224 and the second raised portion 225 are barbed structures facing each other and are disposed on a front and a middle of a top surface of the top board 222, respectively. The first raised portion 224 has a first oblique surface 2241 for use in insertion and a first vertical surface 2242 adapted to abut against a side of the top edge 1421 for the purpose of fixation. Likewise, the second raised portion 225 has a second oblique surface 2251 for use in insertion and a second vertical surface 2252 adapted to abut against another side of the top edge 1421 for the purpose of fixation. The first oblique surface 2241 and the second oblique surface 2251 face two ends of the air duct 22, respectively. The first vertical surface 2242 and the second vertical surface 2252 face each other. In other embodiments, the first raised portion 224 and the second raised portion 225 are not limited to be disposed on the top board 222; the top edge 1421 could be changed to be disposed on one of the two opposite sides of the air duct opening 142, and the first raised portion 224 and the second raised portion 225 could be correspondingly changed to be on a side of one of the two side boards 223 that is one the same side as the top edge 1421.

Referring to FIG. 2, in the first embodiment of the present disclosure, when the air duct 20 movably passes through the air duct opening 142 of the front panel 14, the module socket assembly 100 passes through the air duct opening 142 inside out. When a front end of the air duct body 22 passes through the air duct opening 142, the air duct body 22 passes through the air duct opening 142 by the first oblique surface 2241 abutting against the top edge 1421, so that a portion of the air duct body 22 located between the first raised portion 224 and the second raised portion 225 passes through the air duct opening 142; meanwhile, the first vertical surface 2242 of the first raised portion 224 is adapted to stop at an outside of the top edge 1421 and the second vertical surface 2252 of the second raised portion 225 is adapted to stop at an inside of the top edge 1421, so as to restrict the movable range of the air duct 20. In other embodiments, the first raised portion 224 and the second raised portion 225 could be elastomers capable of elastic deformation when the first oblique surface 2241 and the second oblique surface 2251 are compressed, such that the air duct body 22 could pass through the air duct opening 142 inside out more easily; besides, the air duct 20 could be changed to pass through the air duct opening 142 outside in; at that time, the air duct 20 passes through the air duct opening 142 by the second oblique surface 2251 of the second raised portion 225 abutting against the top edge 1421, so that the portion of the air duct body 22 located between the first raised portion 224 and the second raised portion 225 passes through the air duct opening 142.

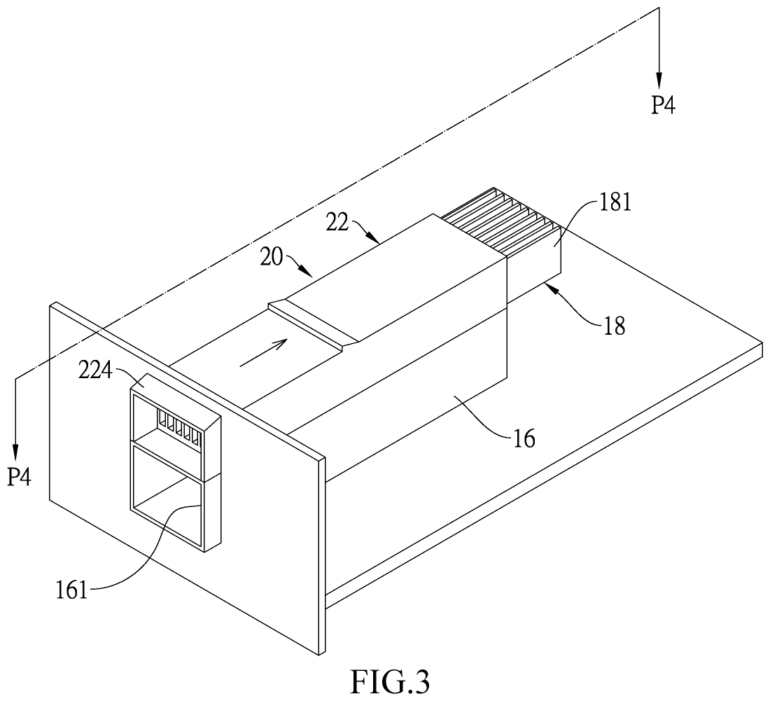

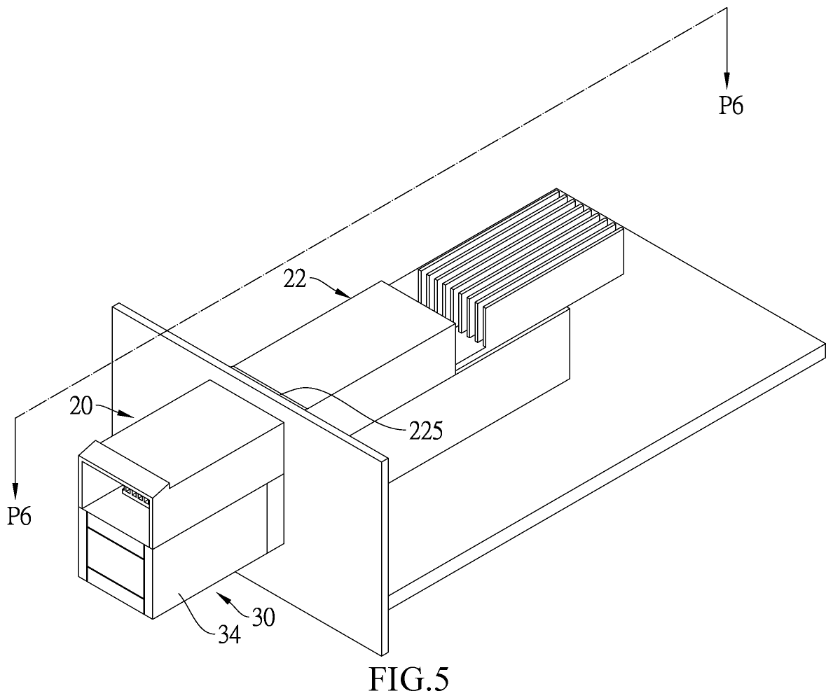

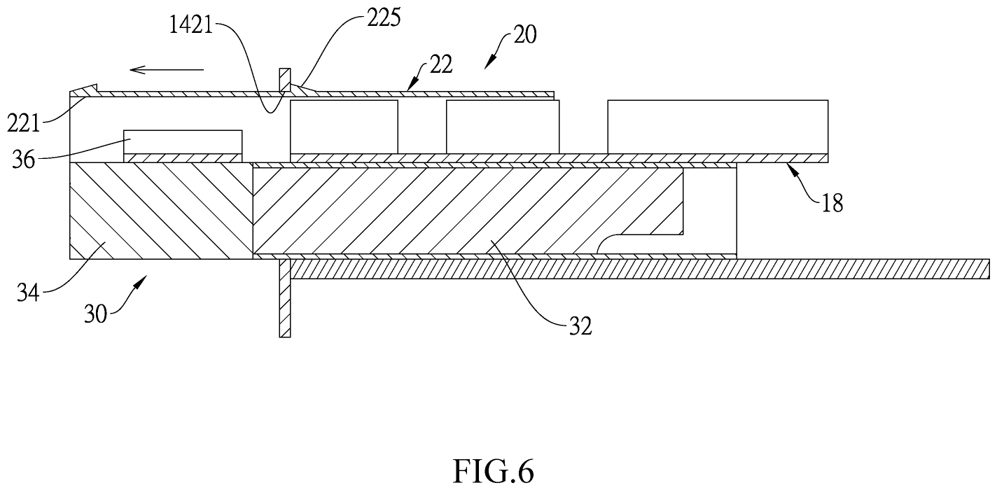

Referring to FIG. 3 and FIG. 4, when the air duct 20 is moved rearward to allow the first raised portion 224 to abut against the outside of the top edge 1421, the air duct 20 covers a larger portion of the heat sink 18. Referring to FIG. 2, the electronic module 30 includes an insertion block 32 and a head portion 34 connected to the insertion block 32. The electronic module 30 is inserted into the module jack 161 through the insertion block 32. In order to further cool the electronic module 30, a module heat sink 36 is coupled to the head portion 34. Referring to FIG. 1, FIG. 5, and FIG. 6, when the air duct body 22 of the air duct 20 is moved frontward to allow the second raised portion 225 abutting against the inside of the top edge 1421 for positioning, the air duct body 22 covers the module heat sink 36, so that the air current entered from a front end of the air passage 221 could be forced to entirely pass through the module heat sink 36 and the heat sink 18 behind the module heat sink 36, thereby enhancing the efficiency of cooling down the electronic module 30. Furthermore, after the air duct 20 is moved frontward, a front side of the air duct body 22 could cover the head portion 34 of the electronic module 30, so that the electronic module 30 with a high temperature could be prevented from being accidentally touched, which causes burns.

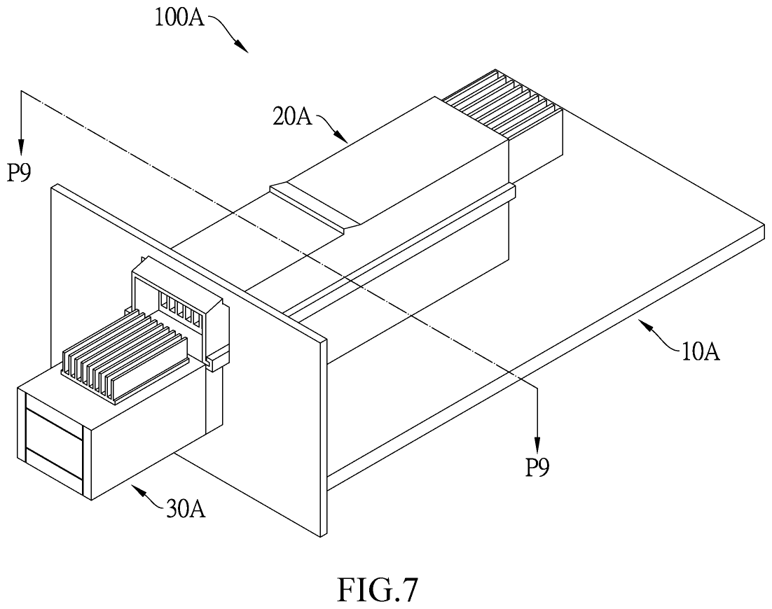

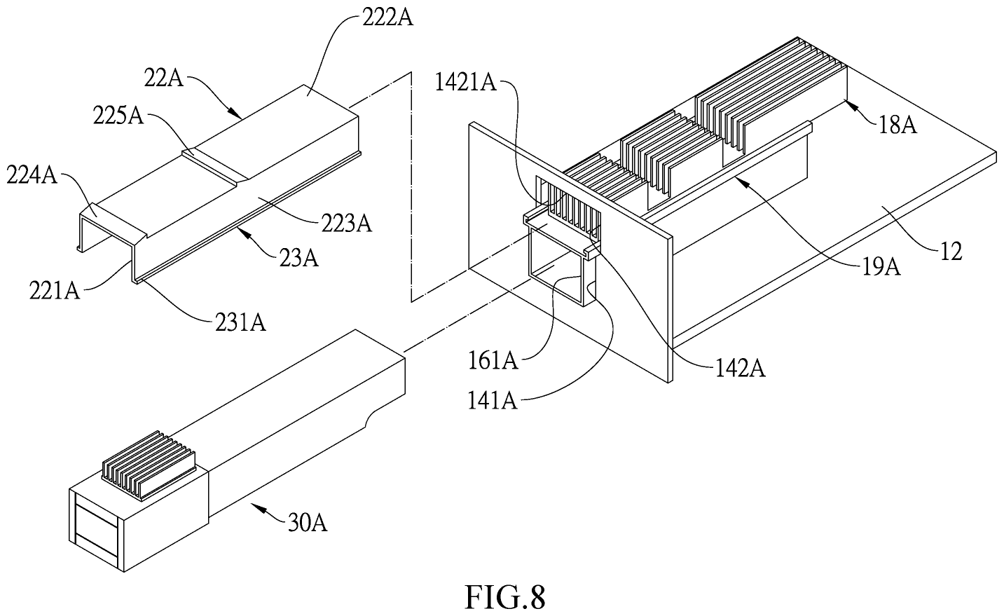

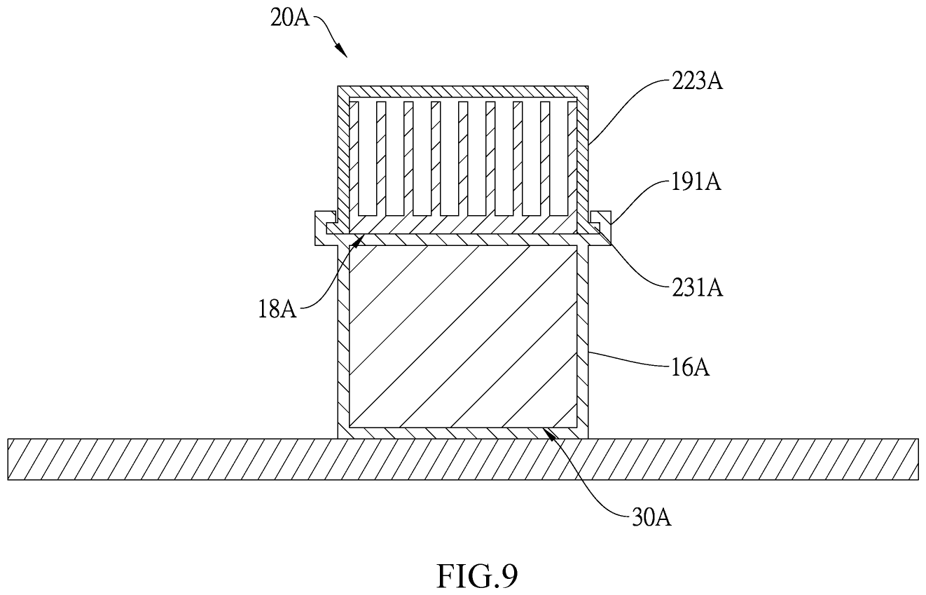

A module socket assembly with an air duct 100A according to a second embodiment of the present disclosure is illustrated in FIG. 7 to FIG. 9 and the air duct 20 in the first embodiment is slidingly disposed on the module casing 16. In the second embodiment, the module socket assembly with the air duct 100A includes a module socket 10A and an air duct 20A. The module socket 10A includes a circuit board 12A and a front panel 14A. A module casing 16A is coupled to the circuit board 12A. A front end of the module casing 16A has a module jack 161A. A heat sink 18A is disposed on the module casing 16A. The front panel 14A is disposed on a side of the circuit board 12A. A position of the front panel 14A corresponding to the module casing has a module casing opening 141A corresponding to the module casing 16A, such that a front end of the module casing 16A passes through the module casing opening 141A. A portion of the front panel 14A adjacent to the module casing opening 141A has an air duct opening 142A. More specifically, the air duct opening 142A is disposed on a portion of the front panel 14A located directly in front of the heat sink 18A. The air duct opening 142A and the module casing opening 141A communicates with each other vertically. A top side of the air duct opening 142A has a top edge 1421A.

The air duct 20A has an air duct body 22A. The air duct body 22A passes through the air duct opening 142A in an inwardly and outwardly movable manner (i.e., the air duct body 22 of the air duct 20A passes through the air duct opening 142 in a movable manner along a front-rear direction). The air duct body 22A covers at least part of the heat sink 18A. An air passage 221A extending in the front-rear direction is formed inside the air duct body 22A. The at least part of the heat sink 18A is located in the air passage 221A. A first raised portion 224A and a second raised portion 225A are disposed on a top surface of the air duct body 22A located on an external portion and an internal portion of the front panel 14A, respectively. The first raised portion 224A is adapted to stop at an outside of the top edge 1421A, and the second raised portion 225A is adapted to stop at an inside of the top edge 1421A, so as to restrict the movable range of the air duct 20A.

The air duct body 22A has a top board 222A. Two side boards 223A are formed by extending downward respectively from a left edge and a right edge of the top board 222A. The two side boards 223A are located on a left side and a right side of the heat sink 18A, respectively. A top surface of the module casing 16A and an inner wall of the air duct body 22A jointly enclose the at least part of the heat sink 18A, so that air current passing through the air duct 20A could completely pass through the heat sink 18A, thereby enhancing the heat dissipation efficiency of the heat sink 18A with respect to the module casing 16A and the efficiency of cooling down an electronic module 30A inserted into the module casing 16A.

The main difference between the second embodiment and the first embodiment is that a top of the module casing 16A in the second embodiment has a top rail 19A extending in the front-rear direction. More specifically, two hook-shaped arms 191A of the top rail 19A are respectively connected to a top edge of a left-side surface and a right-side surface of the module casing 16A. The air duct body 22A has a bottom slide portion 23A. The bottom slide portion 23A is slidingly disposed on the top rail 19A. More specifically, two outer ribs 231A extending in the front-rear direction are respectively provided on a bottom edge of an outer surface of the two side boards 223A. The two outer ribs 231A are confined between the two hook-shaped arms 191A to be slidable along the front-rear direction. The module socket 10A, the air duct 20A, and the electronic module 30A in the second embodiment are identical to the counterparts in the first embodiment in terms of structures of other portions, functions, and effects.

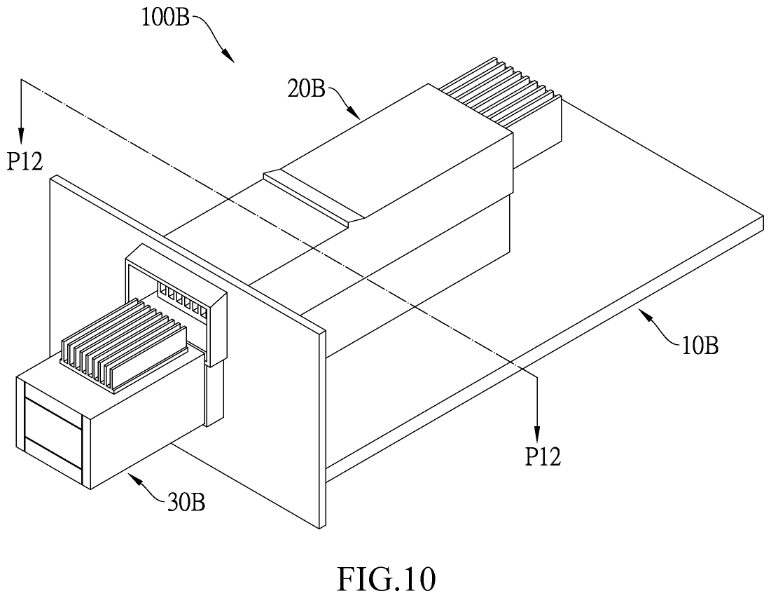

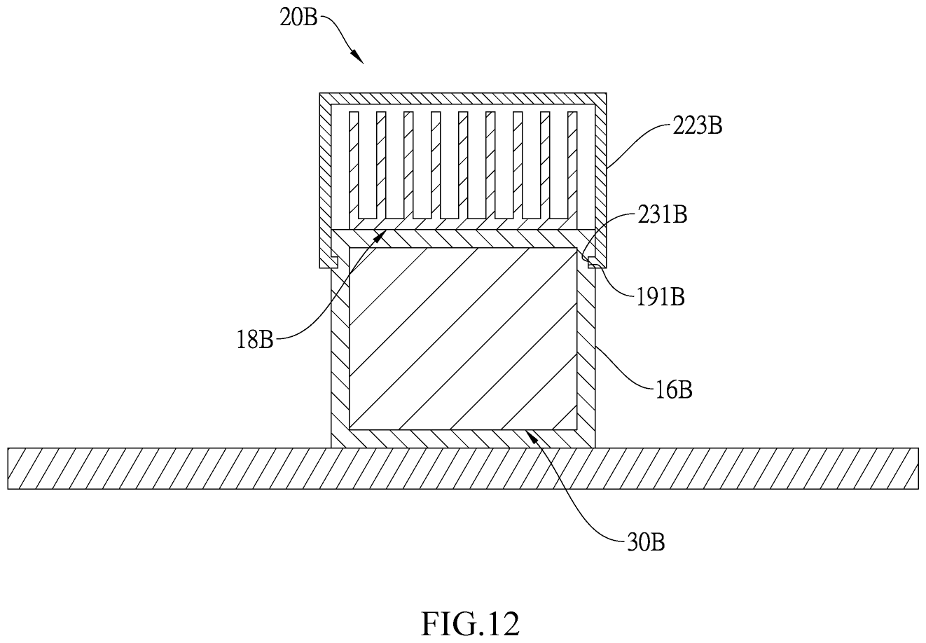

A module socket assembly with an air duct 100B according to a third embodiment of the present disclosure is illustrated in FIG. 10 and FIG. 12 and the air duct 20 in the first embodiment is slidingly disposed on the module casing 16. In the third embodiment, the module socket assembly with the air duct 100B includes a module socket 10B and an air duct 20B. The module socket 10B includes a circuit board 12B and a front panel 14B. A module casing 16B is coupled to the circuit board 12B. A front end of the module casing 16B has a module jack 161B. A heat sink 18B is disposed on the module casing 16B. The front panel 14B is disposed on a side of the circuit board 12B. A position of the front panel 14B corresponding to the module casing 16B has a module casing opening 141B, such that a front end of the module casing 16B passes through the module casing opening 141B. A portion of the front panel 14B adjacent to the module casing opening 141B has an air duct opening 142B. More specifically, the air duct opening 142B is disposed on a portion of the front panel 14B located directly in front of the heat sink 18B. The air duct opening 142B and the module casing opening 141A communicate with each other vertically. A top side of the air duct opening 142B has a top edge 1421B.

The air duct 20B has an air duct body 22B. The air duct body 22B passes through the air duct opening 142B in an inwardly and outwardly movable manner (i.e., the air duct body 22 of the air duct 20B passes through the air duct opening 142 in a movable manner along a front-rear direction). The air duct body 22B covers at least part of the heat sink 18B. An air passage 221B extending in the front-rear direction is formed inside the air duct body 22B. The at least part of the heat sink 18A is located in the air passage 221A. A first raised portion 224B and a second raised portion 225B are disposed on a top surface of the air duct body 22B located on an external portion and an internal portion of the front panel 14B, respectively. The first raised portion 224B is adapted to stop at an outside of the top edge 1421B, and the second raised portion 225B is adapted to stop at an inside of the top edge 1421B, so as to restrict the movable range of the air duct 20B.

The air duct body 22B has a top board 222B. Two side boards 223B are formed by extending downward respectively from a left edge and a right edge of the top board 222B. The two side boards 223B are located on a left side and a right side of the heat sink 18B, respectively. A top surface of the module casing 16B and an inner wall of the air duct body 22B jointly enclose the at least part of the heat sink 18B, so that air current passing through the air duct 20B could completely pass through the heat sink 18B, thereby enhancing the heat dissipation efficiency of the heat sink 18B with respect to the module casing 16B and the efficiency of cooling down an electronic module 30B inserted into the module casing 16B.

The main difference between the third embodiment and the first embodiment is that a top of the module casing 16B has a top rail 19B extending in the front-rear direction. More specifically, two sliding grooves 191B of the top rail 19B extending in the front-rear direction are disposed on a top of a left-side surface and a right-side surface of the module casing 16B. The air duct body 22B has a bottom slide portion 23B, and the bottom slide portion 23B is slidingly disposed on the top rail 19B. More specifically, two inner rib 231B of the bottom slide portion 23B extending in the front-rear direction are respectively provided on a bottom edge of an inner surface of the two side boards 223B. The two inner ribs 231B slidably fit in the two sliding grooves 191B in the front-rear direction, respectively. The module socket 10B, the air duct 20B, and the electronic module 30B in the third embodiment are identical to the counterparts in the first embodiment in terms of structures of other portions, functions, and effects.

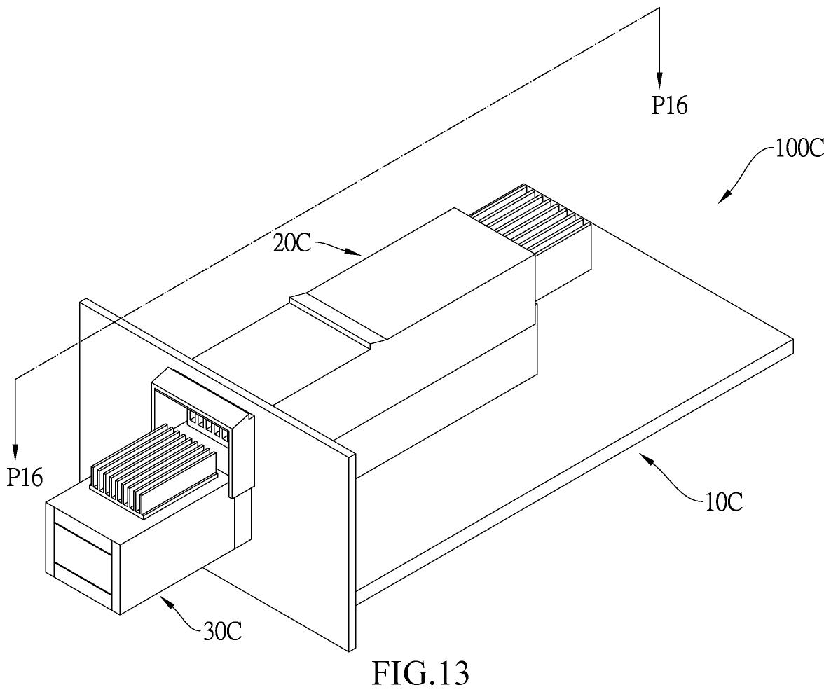

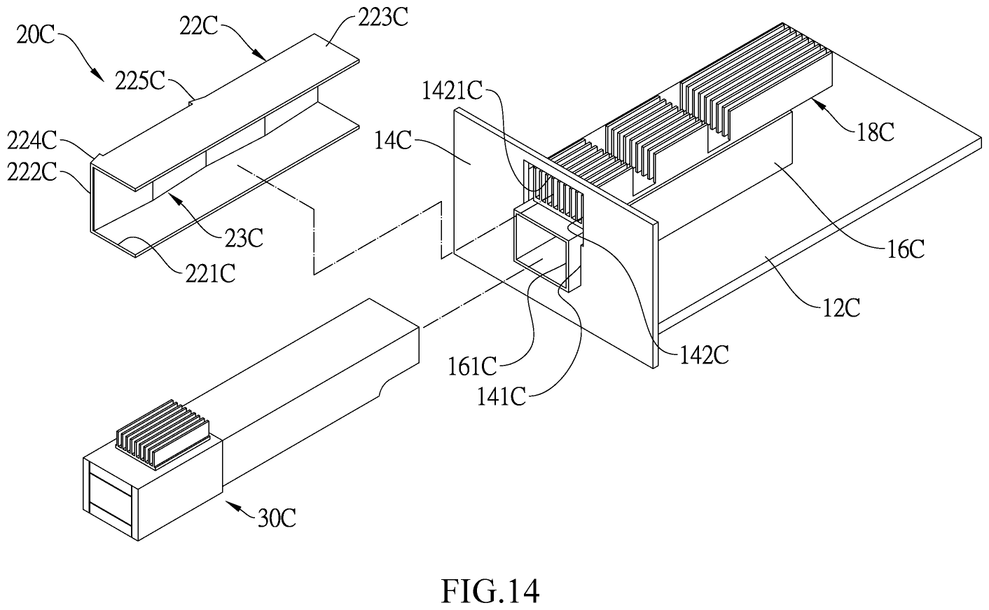

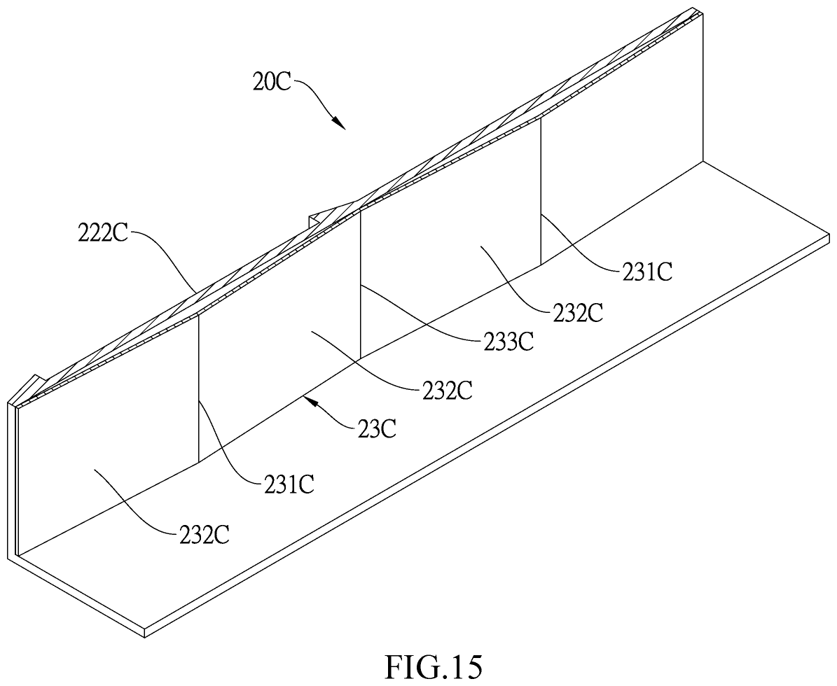

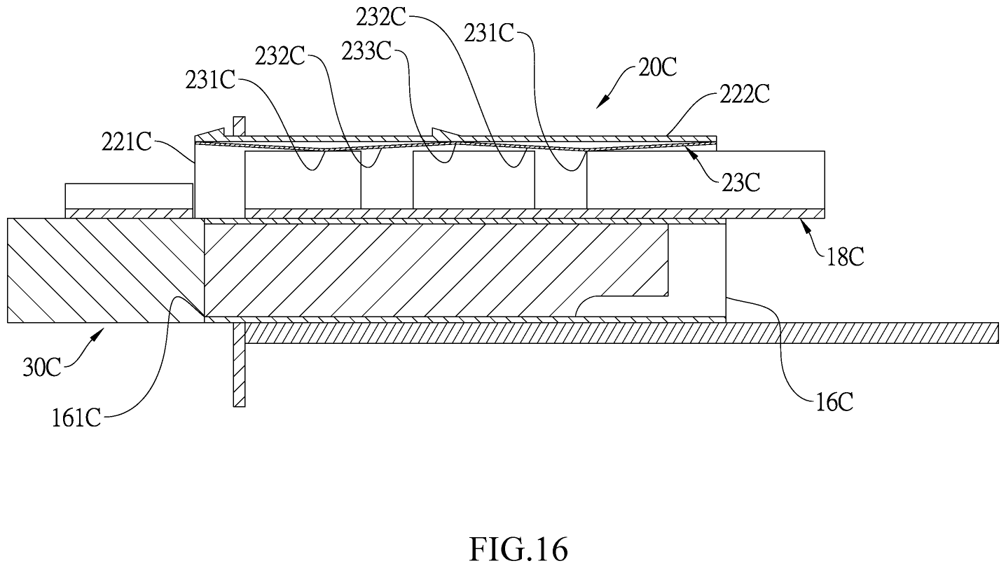

A module socket assembly with an air duct 100C according to a fourth embodiment of the present disclosure is illustrated in FIG. 13 to FIG. 16 and the air duct 20 in the first embodiment has therein a guiding plate. In the fourth embodiment, the module socket assembly with the air duct 100C includes a module socket 10C and an air duct 20C. The module socket 10C includes a circuit board 12C and a front panel 14C. A module casing 16C is coupled to the circuit board 12C. A front end of the module casing 16C has a module jack 161C. A heat sink 18C is disposed on the module casing 16C. The front panel 14C is disposed on a side of the circuit board 12C. A position of the front panel 14C corresponding to the module casing 16C has a module casing opening 141C corresponding to the module casing 16C, such that a front end of the module casing 16C passes through the module casing opening 141C. A portion of the front panel 14C adjacent to the module casing opening 141C has an air duct opening 142C module casing. More specifically, the air duct opening 142C is disposed on a portion of the front panel 14C located directly in front of the heat sink 18C. The air duct opening 142C and the module casing opening 141A communicate with each other vertically. A top side of the air duct opening 142C has a top edge 1421C.

The air duct 20C has an air duct body 22C. The air duct body 22C movably passes through the air duct opening 142C. The air duct body 22C covers at least part of the heat sink 18C. An air passage 221C extending in a front-rear direction is formed inside the air duct body 22C. The at least part of the heat sink 18A is located in the air passage 221A. A first raised portion 224C and a second raised portion 225C are disposed on a top surface of the air duct body 22C located on an external portion and an internal portion of the front panel 14C, respectively. The first raised portion 224C is adapted to stop at an outside of the top edge 1421C, and the second raised portion 225C is adapted to stop at an inside of the top edge 1421C, so as to restrict the movable range of the air duct 20C.

The air duct body 22C has a top board 222C. Two side boards 223C are formed by extending downward respectively from a left edge and a right edge of the top board 222C. The two side boards 223C are located on a left side and a right side of the heat sink 18C, respectively. Two bottom edges of the two side boards 223C extend to a top of a left side and a right side of the module casing 16C, respectively. A top surface of the module casing 16C and an inner wall of the air duct body 22C jointly enclose at least part of the heat sink 18C, so that air current passing through the air duct 20C could completely pass through the heat sink 18C, thereby enhancing the heat dissipation efficiency of the heat sink 18C with respect to the module casing 16C and the efficiency of cooling down an electronic module 30C inserted into the module casing 16C.

The main difference between the fourth embodiment and the first embodiment is that a guiding plate 23C is coupled to a top portion inside the air duct 20C. More specifically, the guiding plate 23C is coupled to a bottom surface of the top board 222C. The guiding plate 23C is an elongated plate extending in the front-rear direction and at least having two peak portions 231C that protrude downward and are arranged at intervals in the front-rear direction. Two oblique portions 232C are respectively formed on a front side and a rear side of each of the peak portions 231C, and a trough portion 233C is formed between two adjacent oblique portions 232C. The peak portions 231C of the guiding plate 23C slidably abut against a top of the heat sink 18C, such that when the air current passes through the air passage 221C inside the air duct 20C, the air current could be guided by a wavy shape of the guiding plate 23C to flow wavily, thereby further enhancing the heat dissipation efficiency of the heat sink 18C and the efficiency of cooling down an electronic module 30C. The module socket 10C, the air duct 20C, and the electronic module 30C in the fourth embodiment are identical to the counterparts in the first embodiment in terms of structures of other portions, functions, and effects.

It must be pointed out that the embodiments described above are only some preferred embodiments of the present disclosure. All equivalent structures which employ the concepts disclosed in this specification and the appended claims should fall within the scope of the present disclosure.

What is claimed is:

1. A module socket assembly, comprising:
a module socket comprising a circuit board and a front panel disposed on a side of the circuit board, wherein a module casing is disposed on the circuit board; an end of the front panel corresponding to the module casing has a module casing opening; a front end of the module casing passes through the module casing opening and has a module jack; a portion of the front panel adjacent to the module casing opening has an air duct opening; and
an air duct having an air duct body adapted to cover the module casing; the air duct body passes through the air duct opening and has a top board; two side boards are formed by extending downward respectively from two opposite edges of the top board; an air passage that is extending is formed between the top board and the two side boards.

2. The module socket assembly as claimed in claim 1, wherein the air duct opening communicates with the module casing opening; the air duct body movably passes through the air duct opening.

3. The module socket assembly as claimed in claim 2, wherein the air duct opening has a top edge; a first raised portion and a second raised portion are respectively disposed on the air duct body, wherein the first raised portion is adapted to stop at a side of the top edge of the air duct opening, and the second raised portion is adapted to stop at another side of the top edge of the air duct opening.

4. The module socket assembly as claimed in claim 3, wherein the first raised portion has a first oblique surface and a first vertical surface, and the second raised portion has a second oblique surface and a second vertical surface; the first oblique surface and the second oblique surface face two ends of the air duct, respectively; the first vertical surface and the second vertical surface face each other.

5. The module socket assembly as claimed in claim 2, further comprising an electronic module, wherein the electronic module comprises an insertion block and a head portion connected to the insertion block; the insertion block is inserted into the module jack; a module heat sink is disposed on the head portion; the air duct body covers the module heat sink after being moved frontward.

6. The module socket assembly as claimed in claim 3, further comprising an electronic module, wherein the electronic module comprises an insertion block and a head portion connected to the insertion block; the insertion block is inserted into the module jack; a module heat sink is disposed on the head portion; when the second raised portion abuts against the another side of the top edge of the air duct opening, the air duct body covers the module heat sink.

7. The module socket assembly as claimed in claim 2, wherein a top rail extending in a front-rear direction is disposed on a top of the module casing; the air duct body has a bottom slide portion slidingly disposed on the top rail.

8. The module socket assembly as claimed in claim 3, wherein a top rail extending in a front-rear direction is disposed on a top of the module casing; the air duct body has a bottom slide portion slidingly disposed on the top rail.

9. The module socket assembly as claimed in claim 4, wherein a top rail extending in a front-rear direction is disposed on a top of the module casing; the air duct body has a bottom slide portion slidingly disposed on the top rail.

10. The module socket assembly as claimed in claim 7, wherein two hook-shaped arms of the top rail are respectively connected to a top edge of a left-side surface and a top edge of a right-side surface of the module casing; two outer ribs of the bottom slide portion extending in the front-rear direction are respectively disposed on a bottom edge of an outer surface of the two side boards; the two outer ribs are confined between the two hook-shaped arms to be slidable in the front-rear direction.

11. The module socket assembly as claimed in claim 8, wherein two hook-shaped arms of the top rail are respectively connected to a top edge of a left-side surface and a top edge of a right-side surface of the module casing; two outer ribs of the bottom slide portion extending in the front-rear direction are respectively disposed on a bottom edge of an outer surface of the two side boards; the two outer ribs are confined between the two hook-shaped arms to be slidable in the front-rear direction.

12. The module socket assembly as claimed in claim 9, wherein two hook-shaped arms of the top rail are respectively connected to a top edge of a left-side surface and a top edge of a right-side surface of the module casing; two outer ribs of the bottom slide portion extending in the front-rear direction are respectively disposed on a bottom edge of an outer surface of the two side boards; the two outer ribs are confined between the two hook-shaped arms to be slidable in the front-rear direction.

13. The module socket assembly as claimed in claim 7, wherein two sliding grooves of the top rail extending in the front-rear direction are respectively disposed on a top of a left-side surface and a top of a right-side surface of the module casing; two inner ribs of the bottom slide portion extending in the front-rear direction are respectively disposed on a bottom edge of an inner surface of the two side boards; the two inner ribs slidably fit in the two sliding grooves in the front-rear direction, respectively.

14. The module socket assembly as claimed in claim 8, wherein two sliding grooves of the top rail extending in the front-rear direction are respectively disposed on a top of a left-side surface and a top of a right-side surface of the module casing; two inner ribs of the bottom slide portion extending in the front-rear direction are respectively disposed on a bottom edge of an inner surface of the two side boards; the two inner ribs slidably fit in the two sliding grooves in the front-rear direction, respectively.

15. The module socket assembly as claimed in claim 9, wherein two sliding grooves of the top rail extending in the front-rear direction are respectively disposed on a top of a left-side surface and a top of a right-side surface of the module casing; two inner ribs of the bottom slide portion extending in the front-rear direction are respectively disposed on a bottom edge of an inner surface of the two side boards; the two inner ribs slidably fit in the two sliding grooves in the front-rear direction, respectively.

16. The module socket assembly as claimed in 1, wherein a guiding plate is coupled to a bottom surface of the top board and at least has two peak portions arranged at intervals in a front-rear direction; two oblique portions are respectively formed on a front side and a back side of each of the two peak portions; a trough portion is formed between two adjacent oblique portions.

17. The module socket assembly as claimed in 2, wherein a guiding plate is coupled to a bottom surface of the top board and at least has two peak portions arranged at intervals in a front-rear direction; two oblique portions are respectively formed on a front side and a back side of each of the two peak portions; a trough portion is formed between two adjacent oblique portions.

18. The module socket assembly as claimed in 3, wherein a guiding plate is coupled to a bottom surface of the top board and at least has two peak portions arranged at intervals in a front-rear direction; two oblique portions are respectively formed on a front side and a back side of each of the two peak portions; a trough portion is formed between two adjacent oblique portions.

19. The module socket assembly as claimed in 4, wherein a guiding plate is coupled to a bottom surface of the top board and at least has two peak portions arranged at intervals in a front-rear direction; two oblique portions are respectively formed on a front side and a back side of each of the two peak portions; a trough portion is formed between two adjacent oblique portions.
